(19) United States
(12) Patent Application Publication
(10) Pub. No.: US 2025/0240939 A1
(43) Pub. Date: Jul. 24, 2025

(54) SEMICONDUCTOR DEVICE AND METHOD OF MANUFACTURING THE SAME

(71) Applicant: Samsung Electronics Co., Ltd., Suwon-si (KR)

(72) Inventors: Moonil JUNG, Suwon-si (KR); Sangwook KIM, Suwon-si (KR)

(73) Assignee: Samsung Electronics Co., Ltd., Suwon-si (KR)

(21) Appl. No.: 18/976,813

(22) Filed: Dec. 11, 2024

(30) Foreign Application Priority Data
Jan. 24, 2024 (KR) 10-2024-0010786

(51) Int. Cl. H10B 12/00

(52) U.S. Cl. CPC H10B 12/315; H10B 12/05

(57) ABSTRACT

Provided are a semiconductor device and a method of manufacturing the same. The semiconductor device of the disclosure may include a lower electrode, an upper electrode spaced apart from the lower electrode, a channel between the lower electrode and the upper electrode, a gate insulating layer provided in the channel, and a gate electrode provided in the gate insulating layer, wherein the channel may include a plurality of oxide semiconductor layers and at least one aluminum oxide layer, the plurality of oxide semiconductor layers being spaced apart from each other, and the at least one aluminum oxide layer being inserted between the plurality of oxide semiconductor layers.

### CROSS-REFERENCE TO RELATED APPLICATION

This application is based on and claims priority under 35 U.S.C. § 119 to Korean Patent Application No. 10-2024-0010786, filed on Jan. 24, 2024, in the Korean Intellectual Property Office, the disclosure of which is incorporated by reference herein in its entirety.

### BACKGROUND

### 1. Field

The disclosure relates to a semiconductor device configured to ensure thermal stability by providing an aluminum oxide layer inside a channel including an oxide semiconductor layer, and to a method of manufacturing the semiconductor device.

### 2. Description of the Related Art

Transistors are semiconductor devices that perform electrical switching and have been used in various types of integrated circuit (IC) devices, including memories, driving ICs, and logic devices. In order to increase the degree of integration of IC devices, the space allocated for transistors provided in the IC devices has rapidly decreased, and accordingly, research has been conducted to reduce the size of transistors while maintaining performance.

With the integration of semiconductor devices, channel lengths of tens to several nanometers are required. As smaller channel lengths may lead to increased chances of tunneling current, it may be important to improve a subthreshold swing (SS) and on/off ratio to reduce off-current and clearly identify between on and off states. However, silicon-based transistors have a high off-current, and as the transistors decrease in size, off-current problems worsen. In contrast, oxide semiconductors have a side bandgap compared to silicon and have a lower off-current than silicon channels, and thus are suitable for transistors to be miniaturized.

### SUMMARY

Provided is a semiconductor device configured to ensure thermal stability by providing an aluminum oxide layer inside a channel including an oxide semiconductor layer.

Provided is a method of manufacturing a semiconductor device including an aluminum oxide layer inside a channel.

Additional aspects will be set forth in part in the description which follows and, in part, will be apparent from the description, or may be learned by practice of the presented embodiments of the disclosure.

According to an aspect of the disclosure, a semiconductor device includes a lower electrode;
an upper electrode spaced apart from the lower electrode; a channel between the lower electrode and the upper electrode, the channel including at least one aluminum oxide layer and a plurality of oxide semiconductor layers, each of the at least one aluminum oxide layer between two of the plurality of oxide semiconductor layers; a gate electrode on the channel; and a gate insulating layer between the gate electrode and the channel, wherein the channel is configured such that each of the plurality of oxide semiconductor layers and the at least one aluminum oxide layer extends in a first direction from the lower electrode to the upper electrode, wherein each of the plurality of oxide semiconductor layers includes indium (In), zinc (Zn), and oxygen (O) or includes In, aluminum (Al), Zn, and O, wherein the channel is in an amorphous state, and wherein the at least one aluminum oxide layer is located in an area that satisfies a following equation

0.05D≤L≤0.35D <Equation>
where L refers to a distance from a center line in a thickness direction of the channel to the at least one aluminum oxide layer, and D refers to a total thickness of the channel in the thickness direction.

The total thickness of the channel is in a range of 1 nanometer (nm) to 10 nm.

A thickness of the at least one aluminum oxide layer, in the thickness direction, is in a range of 0.1 nanometer (nm) to 3 nm.

A ratio of a thickness of the at least one aluminum oxide layer to the total thickness of the channel may be in a range of 1% to 30%.

A number of the at least one aluminum oxide layer may be in a range of 1 to 6.

The channel may have an Al ratio to other metal elements, excluding O, in a range of 0.1 at % to 33 at %.

A content ratio (Al/In) of Al to In in the channel may be in a range of 0.01 to 1.

An interface of the at least one aluminum oxide layer may be in direct contact with the two of the plurality of oxide semiconductor layers.

The semiconductor device may have a gate all around structure.

The channel, the gate insulating layer, and the gate electrode may be arranged such that a longitudinal direction of each of the channel, the gate insulating layer, and the gate electrode is perpendicular to the semiconductor device, and the channel, the gate insulating layer, and the gate electrode may be arranged in a direction horizontal to the semiconductor device.

The channel may have a U-shaped cross-section.

The channel may include a first channel and a second channel, the first channel having an L-shaped cross-sectional shape, and the second channel being symmetrically arranged with the first channel with respect to a direction perpendicular to the semiconductor device.

According to another aspect of the disclosure, a method of manufacturing a semiconductor device depositing a lower electrode on a substrate; forming a channel by depositing a first oxide semiconductor layer on the lower electrode, depositing an aluminum oxide layer on the first oxide semiconductor layer, and depositing a second oxide semiconductor layer on the aluminum oxide layer; depositing a gate insulating layer on the second oxide semiconductor layer; depositing a gate electrode on the gate insulating layer; and depositing an upper electrode on the gate electrode, wherein each of the first oxide semiconductor layer and the second oxide semiconductor layer includes indium (In), zinc (Zn), and oxygen (O) or includes In, aluminum (Al), Zn, and O, wherein the forming the channel includes forming the channel such that channel is in an amorphous state, and wherein the forming channel include forming the first and second oxide semiconductor layers such that the aluminum oxide layer is located in an area that satisfies a following equation

0.05D≤L≤0.35D <Equation>
where L refers to a distance from a center line in a thickness direction of the channel to the aluminum oxide layer, and D refers to a total thickness of the channel.

The first oxide semiconductor layer, the aluminum oxide layer, and the second oxide semiconductor layer may be formed using atomic layer deposition.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 is a schematic diagram of a semiconductor device according to at least one embodiment;

FIGS. 2A, 2B, 2C, 2D, and 2E show examples in which the position of an aluminum oxide layer of a semiconductor device is changed, according to at least one embodiment;

FIG. 3 shows a threshold voltage according to the position of the aluminum oxide layer shown in FIGS. 2A, 2B, 2C, 2D, and 2E;

FIG. 4 shows a channel including one aluminum oxide layer;

FIG. 5 shows a channel including two aluminum oxide layers;

FIG. 6 shows a channel including three aluminum oxide layers;

FIG. 7 shows a threshold voltage according to the content of aluminum in an aluminum oxide layer;

FIG. 8 is a cross-sectional view of a semiconductor device according to at least one embodiment;

FIG. 9 is a cross-sectional view of a semiconductor device according to at least one embodiment;

FIG. 10 is a cross-sectional view of a semiconductor device according to at least one embodiment;

FIG. 11 is a cross-sectional view of a semiconductor device according to at least one embodiment;

FIG. 12 is a flowchart illustrating a method of manufacturing a semiconductor device, according to at least one embodiment;

FIG. 13 is a diagram to describe an atomic layer deposition (ALD) method used in a method of manufacturing a semiconductor device, according to at least one embodiment;

FIGS. 14 to 25 are diagrams illustrating a method of manufacturing a semiconductor device, according to at least one embodiment;

FIG. 26 shows a memory device including a semiconductor device, according to at least one embodiment;

FIG. 27 is a block diagram of a display driver integrated circuit (DDI) including a semiconductor device, and a display apparatus including the DDI, according to at least one embodiment;

FIG. 28 is a circuit diagram of a complementary metal-oxide-semiconductor (CMOS) inverter including a semiconductor device, according to at least one embodiment;

FIG. 29 is a circuit diagram of a CMOS static random access memory (SRAM) device including a semiconductor device, according to at least one embodiment;

FIG. 30 is a circuit diagram of a CMOS NOT-AND (NAND) device including a semiconductor device, according to at least one embodiment;

FIG. 31 is a block diagram of an electronic system including a semiconductor device, according to at least one embodiment; and

FIG. 32 is a block diagram of an electronic system including a semiconductor device, according to at least one embodiment.

### DETAILED DESCRIPTION

Reference will now be made in detail to embodiments, examples of which are illustrated in the accompanying drawings, wherein like reference numerals refer to like elements throughout. In this regard, the present embodiments may have different forms and should not be construed as being limited to the descriptions set forth herein. Accordingly, the embodiments are merely described below, by referring to the figures, to explain aspects. As used herein, the term “and/or” includes any and all combinations of one or more of the associated listed items. Expressions such as “at least one of,” when preceding a list of elements, modify the entire list of elements and do not modify the individual elements of the list.

Hereinafter, the terms “above,” “on,” “below,” or “under” may include not only those that are directly above, below, left, or right in a contact manner, but also those that are above, below, left, or right in a non-contact manner. For example, it will be understood that such spatially relative terms, such as “above,” “top,” etc., are intended to encompass different orientations of the device in use or operation in addition to the orientation depicted in the figures, and that the device may be otherwise oriented (rotated 90 degrees or at other orientations) and the spatially relative terms used herein interpreted accordingly.

Additionally, whenever a range of values is enumerated, the range includes all values within the range as if recorded explicitly clearly, and may further include the boundaries of the range. Accordingly, the range of “X” to “Y” includes all values between X and Y, including X and Y. Further, when the terms “about” or “substantially” are used in this specification in connection with a numerical value and/or geometric terms, it is intended that the associated numerical value includes a manufacturing tolerance (e.g., ±10%) around the stated numerical value. Further, regardless of whether numerical values and/or geometric terms are modified as “about” or “substantially,” it will be understood that these values should be construed as including a manufacturing or operational tolerance (e.g., ±10%) around the stated numerical values and/or geometry.

Also, in the specification, the functional elements, including those including terms such as “unit,” “block,” “ . . . controller,” etc. denote units that process at least one function or operation, and may be realized by and/or include processing circuitry such as hardware, software, or a combination of hardware and software. For example, the processing circuitry more specifically may include, but is not limited to, a central processing unit (CPU), an arithmetic logic unit (ALU), a digital signal processor, a microcomputer, a field programmable gate array (FPGA), a System-on-Chip (SoC), a programmable logic unit, a microprocessor, application-specific integrated circuit (ASIC), etc. The processing circuitry may include electrical components such as at least one of transistors, resistors, capacitors, etc., and/or electronic circuits including said components.

Hereinafter, a semiconductor device and a method of manufacturing the same according to various embodiments will be described in detail with reference to the accompanying drawings. In the following drawings, the same reference numerals refer to the same elements, and the size of each element in the drawings may be exaggerated for convenience of description. The terms such as first and second may be used to describe various elements, but the elements should not be limited by these terms. Terms are used only to distinguish one element from another.

The singular forms “a,” “an,” and “the” as used herein are intended to include the plural forms as well unless the context clearly indicates otherwise. Also, it will be understood that when a portion is referred to as “including” another element, it may not exclude the other element but may further include the other element unless otherwise described. Also, the size or thickness of each element in the drawings may be exaggerated for clarity of description. In addition, when it is described that a certain material layer is present on a substrate or another layer, the material layer may be present in direct contact with the substrate or the other layer, or a third layer may be present therebetween. Furthermore, because materials forming each layer in the following examples are illustrative, other materials may be used.

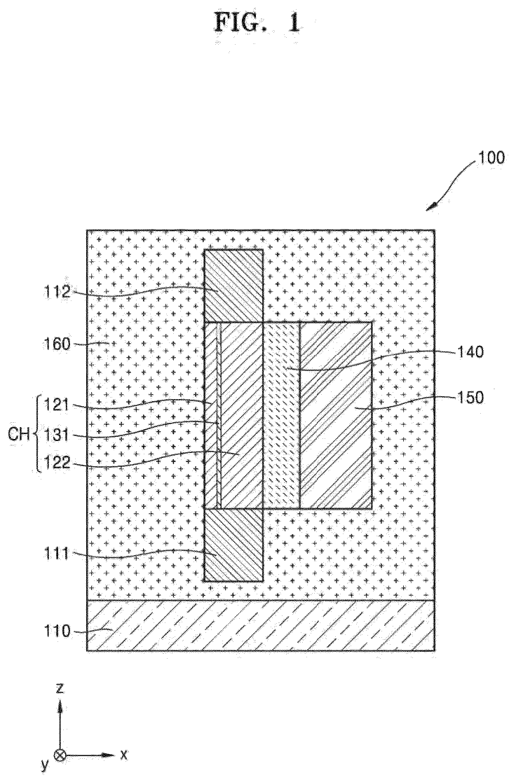

FIG. 1 is a diagram of a semiconductor device 100 according to at least one embodiment.

Referring to FIG. 1, the semiconductor device 100 includes a substrate 110, a lower electrode 111 provided on the substrate 110, a channel CH provided on the lower electrode 111, and an upper electrode 112 provided on the channel CH. A gate electrode 150 may be provided on one side of the channel CH, and a gate insulating layer 140 may be provided between the gate electrode 150 and the channel CH.

In at least one embodiment, the lower electrode 111, the channel CH, and the upper electrode 112 may be sequentially arranged in a direction (e.g., Z-direction) perpendicular to the substrate 110 without intervention of other layers. The lower electrode 111, the channel CH, and the upper electrode 112 may have the same width.

The gate electrode 150 may be arranged such that a longitudinal direction (Z-direction) of the gate electrode 150 is perpendicular to the substrate 110. As used herein, the longitudinal direction refers to a direction in which the length of a corresponding element is relatively long (as illustrated in the drawings). The channel CH, the gate insulating layer 140, and the gate electrode 150 may be arranged in a line in a direction (e.g., the X-direction) horizontal to the substrate 110.

A mold insulating layer 160 may be provided in the substrate 110 to fill an empty space. For example, the lower electrode 111 may be spaced apart from the substrate 110 by the mold insulating layer 160.

The substrate 110 may include an insulating substrate, a semiconductor substrate in which an insulating layer is formed on the surface thereof, and/or a semiconductor substrate. The semiconductor substrate may include, for example, an elemental semiconductor (e.g., silicon (Si), germanium (Ge), and/or the like) and/or a compound semiconductor (e.g., SiGe, a group III-V semiconductor material, and/or the like). The substrate 110 may include, for example, a silicon substrate in which silicon oxide is formed on the surface thereof, but is not limited thereto.

The lower electrode 111 and the upper electrode 112 may each include a metal material and/or a metallically conductive material. For example, each of the lower electrode 111 and the upper electrode 112 may include at least one of tungsten (W), cobalt (Co), nickel (Ni), iron (Fe), titanium (Ti), molybdenum (Mo), chromium (Cr), zirconium (Zr), hafnium (Hf), niobium (Nb), tantalum (Ta), silver (Ag), gold (Au), aluminum (Al), copper (Cu), tin (Sb), vanadium (V), ruthenium (Ru), platinum (Pt), zinc (Zn), magnesium (Mg), and/or the like; and/or may include a conductive nitride including the aforementioned materials.

The channel CH may be between the lower electrode 111 and the upper electrode 112 and may extend lengthwise in the direction perpendicular to the substrate 110 (e.g., the Z-direction). That is, the semiconductor device 100 may have a vertical channel structure in which the channel CH extends lengthwise from the lower electrode 111 to the upper electrode 112. The channel CH may include a plurality of oxide semiconductor layers 121 and 122, and at least one aluminum oxide layer 131 between the plurality of oxide semiconductor layers 121 and 122. For example, the plurality of oxide semiconductor layers 121 and 122 may include a first oxide semiconductor layer 121 and a second oxide semiconductor layer 122. The channel CH may have an amorphous state, thereby reducing off-current.

The plurality of oxide semiconductor layers 121 and 122 and the aluminum oxide layer 131 may extend lengthwise in the direction perpendicular to the substrate 110 (e.g., the Z-direction).

The plurality of oxide semiconductor layers 121 and 122 may include indium (In), Zn, and oxygen (O), and/or may include In, Al, Zn, and O. The aluminum oxide layer 131 may include, for example, Al₂O₃. The plurality of oxide semiconductor layers 121 and 122 may include the same material. However, the disclosure is not limited thereto. For example, the plurality of oxide semiconductor layers 121 and 122 may also include different materials. The plurality of oxide semiconductor layers 121 and 122 may include a different oxide compared to the aluminum oxide layer. In at least one embodiment, the channel CH may include only four elements including In, Al, Zn, and O. In addition, an interface of the aluminum oxide layer 131 may be arranged to be in direct contact with the plurality of oxide semiconductor layers 121 and 122.

The aluminum oxide layer 131 may be arranged at a position deviating from a center line CL in a widthwise direction (e.g., the X-direction) of the channel CH. In this case, the thickness direction of the channel CH refers to the X-direction. As used herein, thickness refers to a relatively short thickness in a widthwise direction.

Next, the position of the aluminum oxide layer 131 is described in detail.

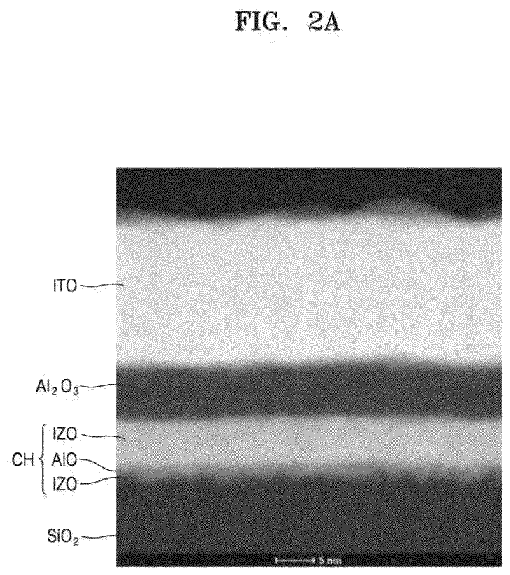

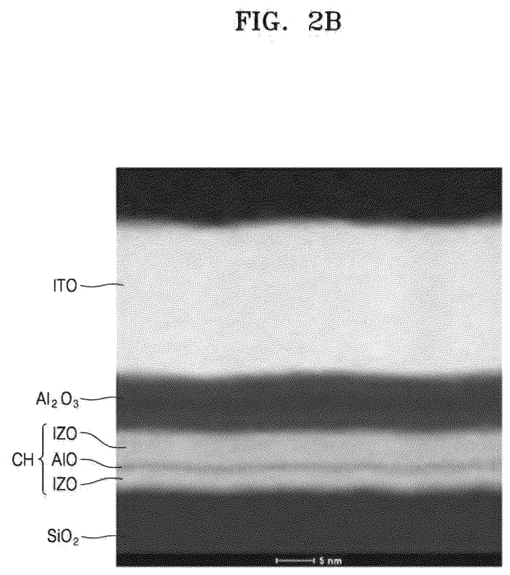

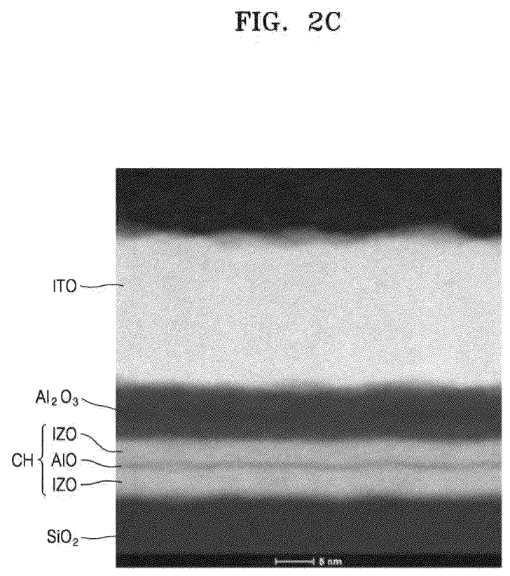

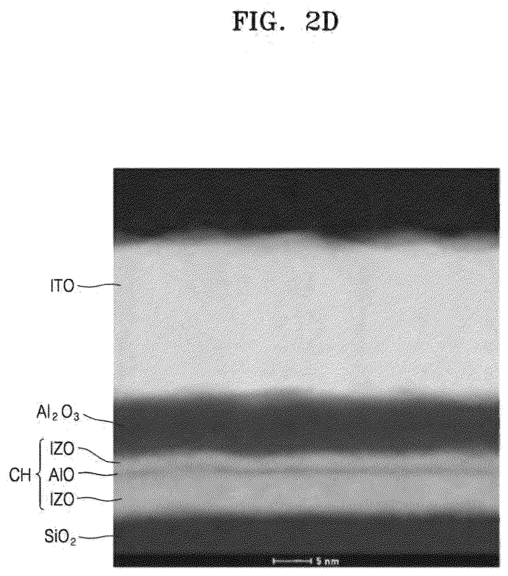

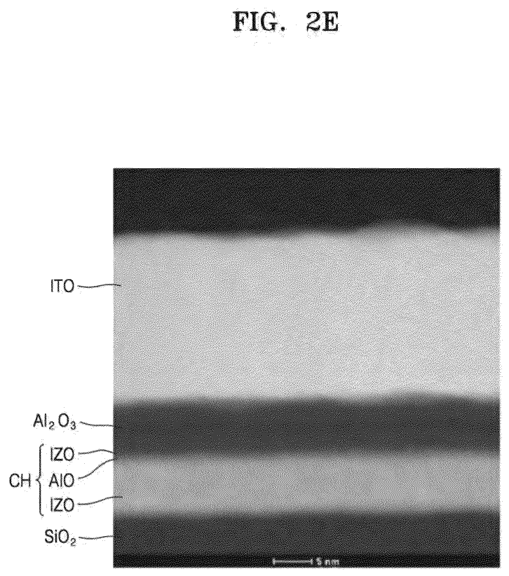

FIGS. 2A to 2D show transmission electron microscope (TEM) images of a layer structure in which an aluminum oxide layer Al₂O₃ is located at different positions in a thickness direction of the channel CH. The layer structure has a layer structure of SiO₂/CH/Al₂O₃/ITO. In this case, SiO₂ corresponds to a substrate on which the channel CH is to be stacked, and the channel CH has a three-layer structure of IZO/AIO/IZO. A composition ratio of In:Al:Zn in the channel CH is 1:0.1:1. In this case, In and Zn represent a composition ratio of the entire oxide semiconductor layer in the channel CH.

The aluminum oxide layer Al₂O₃ on the channel CH may be a gate insulating layer, and ITO may be a gate electrode.

In FIG. 2A, an aluminum oxide layer AIO of the channel CH is located at a distance of (0.36×D) in a downward direction (−X direction) in the drawing from the center line CL in the thickness direction (X-direction) of the channel CH. In this case, D represents a total thickness of the channel CH. In FIG. 2B, the aluminum oxide layer AIO of the channel CH is located at a distance of (0.14×D) in the downward direction (−X direction) from the center line CL in the thickness direction (X-direction) of the channel CH. In FIG. 2C, the aluminum oxide layer AIO of the channel CH is located at the center line CL in the thickness direction (X-direction) of the channel CH. In FIG. 2D, the aluminum oxide layer AIO of the channel CH is located at a distance of (0.14×D) in an upward direction (+X direction) from the center line CL in the thickness direction (X-direction) of the channel CH. In FIG. 2E, the aluminum oxide layer AIO of the channel CH is located at a distance of (0.36×D) in the upward direction (+X direction) from the center line CL in the thickness direction (X-direction) of the channel CH.

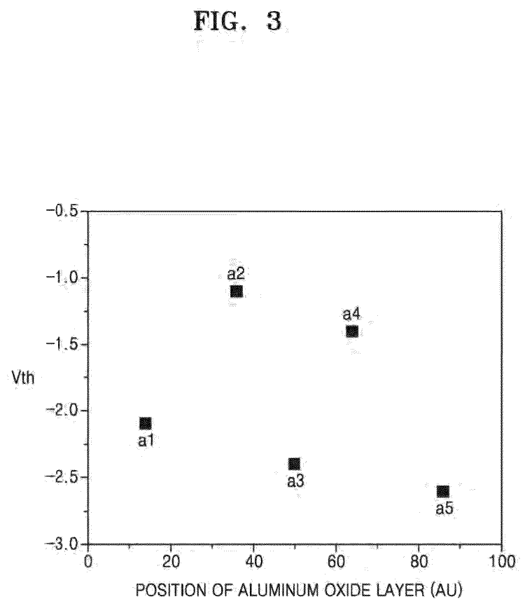

FIG. 3 shows a change in a threshold voltage Vth according to the position of an aluminum oxide layer. In FIG. 3, an x-axis shows a ratio of the position of the aluminum oxide layer to a total channel thickness D. a1 represents an aluminum oxide layer in the layer structure shown in FIG. 2A, a2 represents an aluminum oxide layer in the layer structure shown in FIG. 2B, a3 represents an aluminum oxide layer in the layer structure shown in FIG. 2C, a4 represents an aluminum oxide layer in the layer structure shown in FIG. 2D, and a5 represents an aluminum oxide layer in the layer structure shown in FIG. 2E.

The semiconductor device 100 may improve negative bias thermal instability (NBTI) and positive bias thermal instability (PBTI) characteristics. Due to NBTI, PBTI, etc., carriers are trapped in the gate insulating layer 140 such that a threshold voltage may increase.

Referring to FIG. 3, the closer the threshold voltage is to a gate voltage, that is, to 0 V, the better the performance of the semiconductor device may be. Referring to FIG. 3, in the case of a2 and a4, the threshold voltage appears to be relatively close to 0 V. Moreover, in the case of a1, a3, and a5, the threshold voltage appears to be relatively far from 0 V. For example, in a2 and a4, the threshold voltage Vth appears to be greater than −2 V, and in a1, a3, and a5, the threshold voltage Vth appears to be less than −2 V. Accordingly, with respect to the position of the aluminum oxide layer, points a1, a3, and a5 may be excluded. For example, when a total thickness of the channel CH is D, the aluminum oxide layer may be located at a distance ranging from about 0.05D to about 0.35D from the center line of the channel CH.

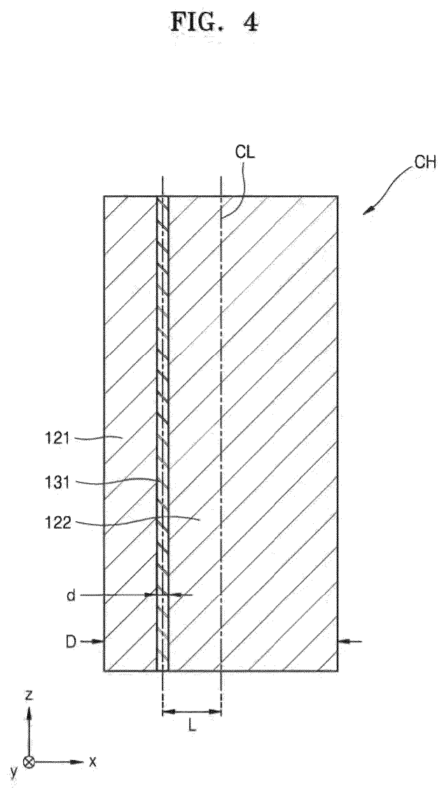

FIG. 4 is an enlarged view of the channel CH including one aluminum oxide layer 131. Based on FIG. 3, the aluminum oxide layer 131 may be located in an area that satisfies the following equation.

0.05D≤L≤0.35D <Equation 1>

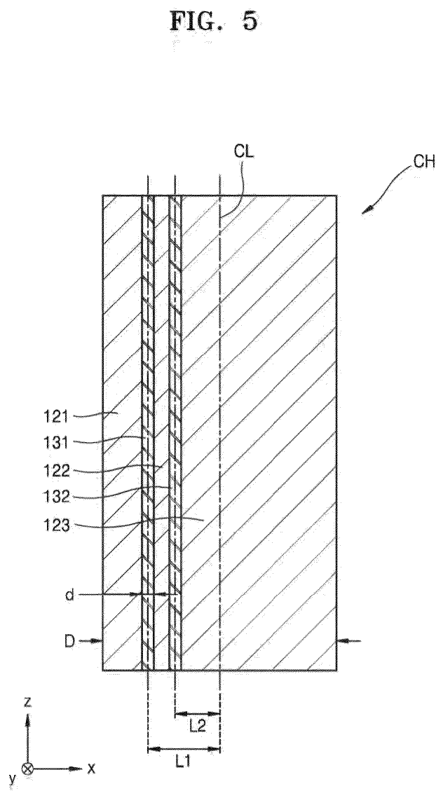

In this case, L refers to a distance from the center line CL in the thickness direction (X-direction) of the channel CH to the aluminum oxide layer 131, and D refers to a total thickness of the channel CH. As used herein, L refers to a distance from the center line CL in the thickness direction (X-direction) of the channel CH to a center line in a thickness direction of the aluminum oxide layer 131. In FIG. 5, the aluminum oxide layer 131 is located on the left side of the center line CL of the channel CH, but the aluminum oxide layer 131 may be arranged on the right side of the center line CL of the channel CH at a position that satisfies Equation 1.

FIG. 5 is an enlarged view of the channel CH including two aluminum oxide layers (e.g., a first aluminum oxide layer 131 and a second aluminum oxide layer 132).

The channel CH may include the first oxide semiconductor layer 121, the second oxide semiconductor layer 122, a third oxide semiconductor layer 123, the first aluminum oxide layer 131 between the first oxide semiconductor layer 121 and the second oxide semiconductor layer 122, and the second aluminum oxide layer 132 between the second oxide semiconductor layer 122 and the third oxide semiconductor layer 123.

The first aluminum oxide layer 131 and the second aluminum oxide layer 132 may be arranged to satisfy the following equations.

0.05D≤L1≤0.35D <Equation 2>

0.05D≤L2≤0.35D <Equation 3>

L1≥L2 <Equation 4>

In this case, L1 refers to a distance from the center line CL in the thickness direction (X-direction) of the channel CH to the first aluminum oxide layer 131, and L2 refers to a distance from the center line CL in the thickness direction (X-direction) of the channel CH to the second aluminum oxide layer 132. In FIG. 5, the first aluminum oxide layer 131 and the second aluminum oxide layer 132 are both located on the left side of the center line CL of the channel CH, but the first aluminum oxide layer 131 may be arranged on the left side of the center line CL of the channel CH, and the second aluminum oxide layer 132 may be arranged on the right side of the center line CL of the channel CH, or the first aluminum oxide layer 131 and the second aluminum oxide layer 132 may both be located on the right side of the center line CL of the channel CH. In the case wherein the first aluminum oxide layer 131 and the second aluminum oxide layer 132 are both located on the same side of the center line CL of the channel CH L1 may be greater than L2. When the first aluminum oxide layer 131 is arranged on the left side of the center line CL of the channel CH and the second aluminum oxide layer 132 is arranged on the right side of the center line CL of the channel CH, the first aluminum oxide layer 131 and the second aluminum oxide layer 132 may be symmetrically arranged with respect to the center line CL. In other words, in the case wherein the first aluminum oxide layer 131 and the second aluminum oxide layer 132 are located on the different sides of the center line CL of the channel CH L1 may be greater than or equal to L2. However, the disclosure is not limited thereto. The first aluminum oxide layer 131 and the second aluminum oxide layer 132 may be asymmetrically arranged with respect to the center line CL.

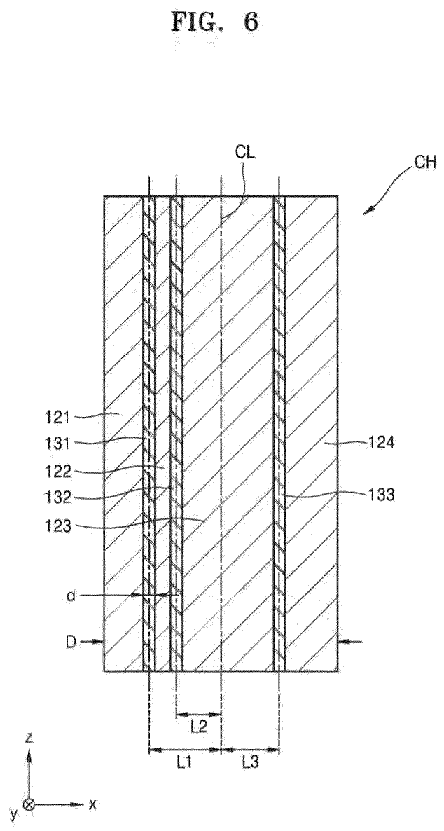

FIG. 6 is an enlarged view of the channel CH including three aluminum oxide layers (e.g., a first aluminum oxide layer 131, a second aluminum oxide layer 132, and a third aluminum oxide layer 133).

The channel CH may include the first oxide semiconductor layer 121, the second oxide semiconductor layer 122, the third oxide semiconductor layer 123, a fourth oxide semiconductor layer 124, the first aluminum oxide layer 131 between the first oxide semiconductor layer 121 and the second oxide semiconductor layer 122, the second aluminum oxide layer 132 between the second oxide semiconductor layer 122 and the third oxide semiconductor layer 123, and the third aluminum oxide layer 133 between the third oxide semiconductor layer 123 and the fourth oxide semiconductor layer 124.

For example, the first aluminum oxide layer 131 and the second aluminum oxide layer 132 may be arranged on the left side of the center line CL, and the third aluminum oxide layer 133 may be arranged on the right side of the center line CL. The first aluminum oxide layer 131 and the second aluminum oxide layer 132 may be arranged to satisfy Equations 2, 3, and 4. The third aluminum oxide layer 133 may be arranged to satisfy the following equation.

0.05D≤L3≤0.35D <Equation 5>

In this case, L3 refers to a distance from the center line CL in the thickness direction (X-direction) of the channel CH to the third aluminum oxide layer 133.

In addition, the first aluminum oxide layer 131, the second aluminum oxide layer 132, and the third aluminum oxide layer 133 may all be arranged on one side, that is, on the left side or right side, with respect to the center line CL.

As described above, in the semiconductor device according to at least one embodiment, the number and positions of aluminum oxide layers may be variously set within a range that satisfies Equation 1.

The first, second, and third aluminum oxide layers 131, 132, and/or 133 may increase oxygen in the channel CH and the gate electrode 150. Such an increase in oxygen may be a factor in increasing the threshold voltage, and thus, an oxygen vacancy created in a thin film of the semiconductor device during the processing of the semiconductor device (e.g., etching, annealing, developing, etc.) may be reduced, and deterioration characteristics caused by a charge trap may be reduced, thereby improving thermal stability and electrical reliability.

In addition, in at least one embodiment, the channel CH may have a thickness D in a range of about 1 nm (nanometer) to about 10 nm. A thickness d of each of the first, second, and third aluminum oxide layers 131, 132, and 133 may be in a range of at least about 0.1 nm to about 1 nm.

In addition, in at least one embodiment, a ratio of a sum of thicknesses of the first, second, and third aluminum oxide layers 131, 132, and 133 to the total channel thickness D may be in a range of about 1% to about 30%. In these cases, an example in which the three aluminum oxide layers (e.g., the first, second, and third aluminum oxide layers 131, 132, and 133) are provided has been described. However, for example, one to six aluminum oxide layers may be provided.

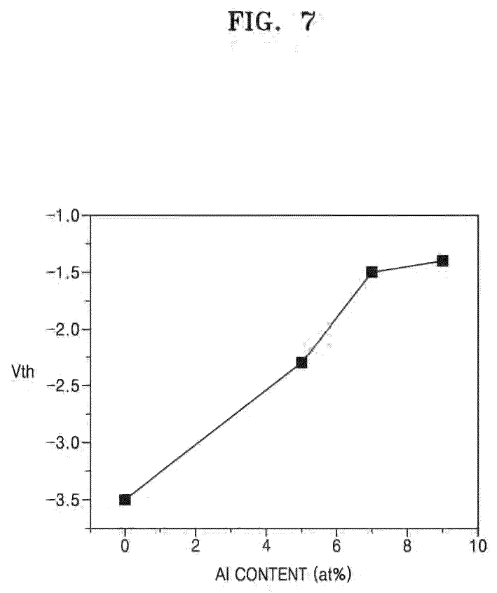

FIG. 7 shows a change in a threshold voltage according to the content of Al in an aluminum oxide layer. The closer the threshold voltage is to a gate voltage, that is, to 0 V, the better the performance of the semiconductor device may be. When the content of Al is 0%, the threshold voltage is relatively far from 0 V, and when the content of Al is 5 at %, 7 at %, and 9 at %, the threshold voltage is relatively close to 0 V. In FIG. 7, cases only up to a case where the content of Al is 9 at % are shown. However, referring to the graph, it may be predicted that the threshold voltage Vth tends to increase close to 0 V even when the content of Al increases to 9 at % or more.

When the channel CH is oxide including In, Al, and Zn, other metal elements excluding O may have a composition ratio of In:Al:Zn=1:1:1. Accordingly, the channel CH of the semiconductor device according to at least one embodiment may have an Al ratio to the other metal elements excluding O in a range of at least about 0.1 at % to about 33 at %. Alternatively, the channel CH may have an Al ratio to the other metal elements excluding O in a range of at least about 3 at % to about 25 at %. Alternatively, the channel CH may have an Al ratio to the other metal elements excluding O in a range of at least about 5 at % to about 20 at %. Moreover, a content ratio (Al/In) of Al to In in the channel CH may be in a range of at least about 0.01 to about 1.

As described above, the semiconductor device 100 according to at least one embodiment includes the first, second, and third aluminum oxide layers 131, 132, and 133 inside the channel CH such that leakage current of the first, second, third, and fourth oxide semiconductor layers 121, 122, 123, and 124 may be reduced, and thermal stability may be improved. The semiconductor device 100 may reduce a delta threshold voltage by limiting the positions of the first, second, and third aluminum oxide layers 131, 132, and 133, and accordingly, PBTI may be improved. This is because the aluminum oxide layers provided in the channel CH stabilize bonds. Based on stable reliability as described above, the degree of freedom in an In composition ratio of the oxide semiconductor layers may be increased, contributing to improving on-current. Also, device stability may be achieved even in a stress environment by controlling interface characteristics of the channel CH and the gate insulating layer.

In addition, in the semiconductor device 100 according to at least one embodiment, an oxide semiconductor is applied to the channel CH, and thus a low off-current, low subthreshold swing (SS), and high on/off ratio are achieved. Accordingly, the semiconductor device 100 may be used in large-area display driving devices as well as memory devices or logic devices. For example, the thermal stability may be improved by applying the semiconductor device 100 to a dynamic random access memory (DRAM) cell vertical transistor, thereby reducing the size of DRAM and increasing memory capacity.

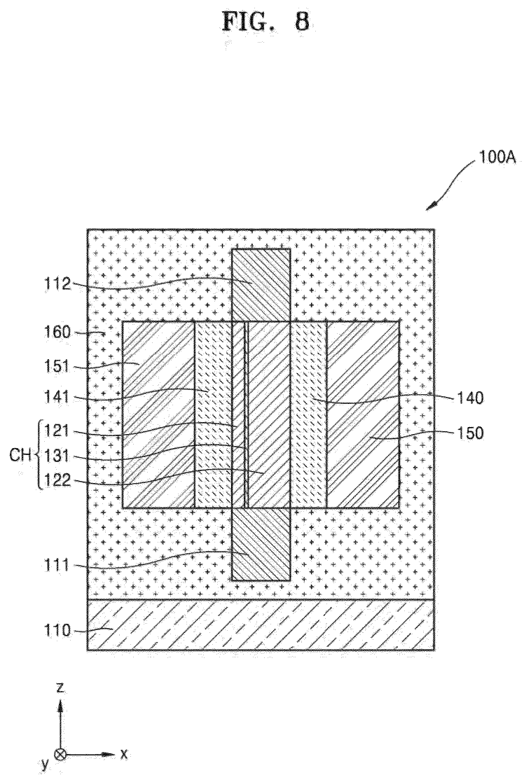

FIG. 8 shows a semiconductor device 100A according to another example. In FIG. 8, elements using the same reference numerals as in FIG. 1 have the same and/or a substantially similar configuration and operational effects as those described with reference to FIG. 1, and thus, detailed descriptions thereof may be omitted herein.

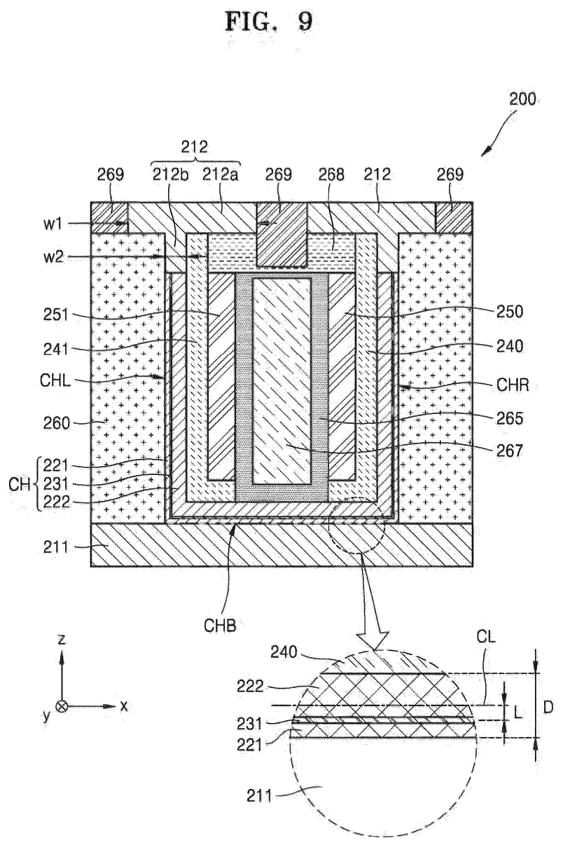

The semiconductor device 100A includes the lower electrode 111, the channel CH, and the upper electrode 112, which are arranged in the direction (Z-direction) perpendicular to the substrate 110. The gate insulating layer 140 may be provided around the channel CH, and the gate electrode 150 may be provided around the gate insulating layer 140. The gate electrode 150 is provided around the channel CH such that an area in which the gate electrode 150 and the channel CH face each other may be expanded, and the short channel effect may be improved. Therefore, when viewed in cross-section, the gate electrode 150 and the gate insulating layer 140 may respectively further include a second region gate electrode 151 and a second gate insulating layer 141. The semiconductor device 100A may be applied to a so-called gate all around structure. FIG. 9 is a diagram of a semiconductor device 200 according to another embodiment.

The semiconductor device 200 may include a lower electrode 211, the channel CH provided on the lower electrode 211, and an upper electrode 212 provided on the channel CH. The lower electrode 211 may be a source electrode, the upper electrode 212 may be a drain electrode, and/or the lower electrode 211 may be a drain electrode and the upper electrode 212 may be a source electrode. As such, the first electrode 211 and the second electrode 212 may also be referred to as source/drain electrodes.

The channel CH may have a U-shaped cross-sectional shape. The channel CH may include a plurality of oxide semiconductor layers 221 and 222, and an aluminum oxide layer 231 between the plurality of oxide semiconductor layers 221 and 222. The plurality of oxide semiconductor layers 221 and 222 and the aluminum oxide layer 231 may each have a U-shaped cross-sectional shape. The channel CH may include a bottom portion CHB in contact with the lower electrode 211, a first vertical extension portion CHR extending from one end of the bottom portion CHB in a direction (e.g., a Z-direction) perpendicular to the lower electrode 211, and a second vertical extension portion CHL extending from the other end of the bottom portion CHB in the direction perpendicular to the lower electrode 211 (e.g., the Z-direction).

A first gate electrode 250 may be spaced apart from the first vertical extension portion CHR, and a second gate electrode 251 may be spaced apart from the second vertical extension portion CHL. A first gate insulating layer 240 may be between the first vertical extension portion CHR and the first gate electrode 250, and a second gate insulating layer 241 may be between the second vertical extension portion CHL and the second gate electrode 251.

The first gate electrode 250 and/or the second gate electrode 251 may extend in a second horizontal direction (e.g., the y-direction). The first gate electrode 250 and the second gate electrode 251 may be spaced apart from each other. The first gate electrode 250 and/or the second gate electrode 251 may form a word line. An electrical signal input to the first gate electrode 250 may not match an electrical signal input to the second gate electrode 251. The first gate electrode 250 may control a channel of the first vertical extension portion CHR, and the second gate electrode 251 may control a channel of the second vertical extension portion CHL.

An insulating liner 265 may be between the first gate electrode 250 and the second gate electrode 251, which are spaced apart from each other. The insulating liner 265 may be conformally arranged on opposing sidewalls of the first gate electrode 250 and the second gate electrode 251 and/or the upper surface of the channel CH. The insulating liner 265 may have an upper surface arranged on the same plane as the first gate electrode 250 and the second gate electrode 251. The insulating liner 265 may include an insulator, for example, silicon nitride. A buried insulating layer 267 may fill a remaining space between the first gate electrode 250 and the second gate electrode 251. The buried insulating layer 267 may include a different insulator, for example, silicon oxide. An upper insulating layer 268 may be arranged on the upper surfaces of the first gate electrode 250, the second gate electrode 251, and/or the buried insulating layer 267. The upper surface of the upper insulating layer 268 may be arranged at the same level as the upper surface of a mold insulating layer 260.

The upper electrode 212 may be arranged over the channel CH. The upper electrode 212 may function as a landing pad. The upper electrode 212 may include an upper left electrode and an upper right electrode. The upper right electrode may be electrically connected to the first vertical extension portion CHR. The upper left electrode may be electrically connected to the second vertical extension portion CHL. The upper right electrode and the upper left electrode may not be electrically connected to each other. The upper electrode 212 may include an upper portion 212a and a lower portion 212b, which have different widths. The upper portion 212a of the upper electrode 212 may be arranged at a higher level than the upper surface of the mold insulating layer 260. The lower portion 212b of the upper electrode 212 may be arranged inside a recess, which is defined between the mold insulating layer 260 and the upper insulating layer 268. In at least one embodiment, the upper portion 212a of the upper electrode 212 may have a first width w1 in a first horizontal direction (x), and the lower portion 212b of the upper electrode 212 may have a second width w2, which is less than the first width w1, in the first horizontal direction (x). The lower portion 212b of the upper electrode 212 may be arranged inside the recess, and the upper portion 212a of the upper electrode 212 may have a bottom surface, which is arranged on the upper surface of the mold insulating layer 260 and the upper surface of the upper insulating layer 268 on the lower portion 212b of the upper electrode 212. Accordingly, the upper electrode 212 may have a T-shaped vertical cross-section. The bottom surface of the lower portion 212b of the upper electrode 212 may be in contact with the upper surface of the first vertical extension portion CHR and/or the second vertical extension portion CHL. Both sidewalls of the lower portion 212b of the upper electrode 212 may be aligned with both sidewalls of the first vertical extension portion CHR and both sidewalls of the second vertical extension portion CHL. The bottom surface of the lower portion 212b of the upper electrode 212 may be arranged at a higher level than the upper surfaces of the first gate electrode 250 and/or the second gate electrode 251, and portions of the sidewalls of the lower portion 212b of the upper electrode 212 may be covered by a first gate insulating layer 250 and/or a second gate insulating layer 251.

An insulating layer 269 surrounding the upper electrode 212 may be arranged on the upper surfaces of the mold insulating layer 260 and the upper insulating layer 268. The semiconductor device 200 may have a vertical channel transistor (VCT) structure including a vertical channel CH, which extends in a direction (z) perpendicular to the lower electrode 211. The second gate insulating layer 241 may have an L-shaped cross-sectional shape, and the first gate insulating layer 240 may have a cross-sectional shape, which is symmetrical to the second gate insulating layer 241 with respect to the buried insulating layer 267. The first gate electrode 250 and the second gate electrode 251 may each have a straight cross-sectional shape. Alternatively, the first gate insulating layer 240 and the second gate insulating layer 241 may have a straight cross-sectional shape like the first gate electrode 250 and the second gate electrode 251.

Moreover, the channel CH is described in more detail. The aluminum oxide layer 231 of the channel CH may be arranged at a distance L ranging from about (0.05×D) to about (0.35×D) from the center line CL of the channel CH. In this case, the center line CL refers to ½ of a total thickness D of the channel CH. As described above, when the aluminum oxide layer 231 is positioned, a threshold voltage of the semiconductor device 200 may be effectively increased, and thermal stabilization may be achieved. The number and positions of the aluminum oxide layer 231 may be variously set within the above position range.

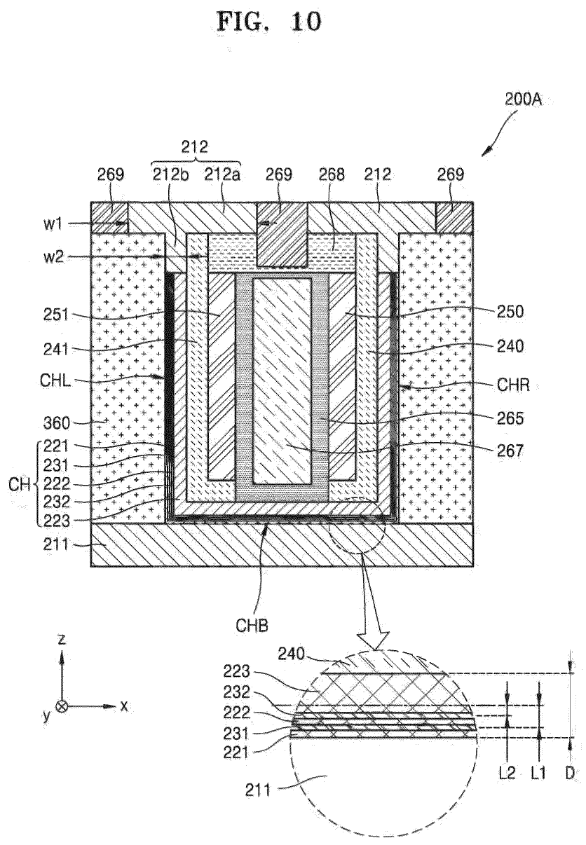

FIG. 10 shows a semiconductor device 200A including a plurality of aluminum oxide layers (e.g., a first aluminum oxide layer 231 and a second aluminum oxide layer 232). In the semiconductor device 200A, the channel CH may have a structure in which a first oxide semiconductor layer 221, the first aluminum oxide layer 231, a second oxide semiconductor layer 222, the second aluminum oxide layer 232, and a third oxide semiconductor layer 223 are sequentially stacked. When a distance from the center line CL of the channel CH to the first aluminum oxide layer 231 is referred to as L1 and a distance from the center line CL of the channel CH to the second aluminum oxide layer 232 is referred to as L2, both L1 and L2 may be in a range of about (0.05×D) to about (0.35×D). The first aluminum oxide layer 231 and the second aluminum oxide layer 232 may also be arranged in the other direction of the center line CL, differently from that shown in FIG. 10.

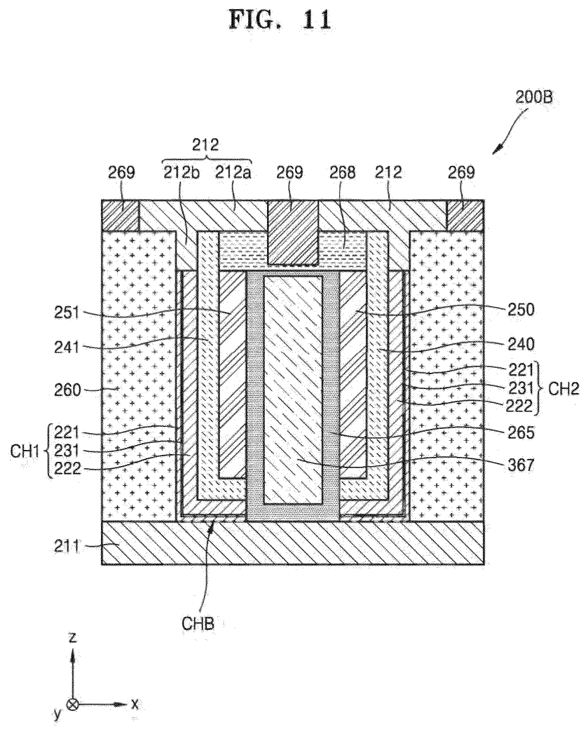

FIG. 11 shows a semiconductor device 200B according to another embodiment.

In FIG. 11, elements using the same reference numerals as in FIG. 10 have substantially the same configuration and operational effects, and thus, detailed descriptions thereof are omitted herein.

When compared to FIG. 10, the shape of the channel CH may be different in FIG. 11. The channel CH may include a first channel CH1 and a second channel CH2. The first channel CH1 may have an L-shaped cross-sectional shape, and the second channel CH2 may have a symmetrical shape with respect to the first channel CH1 in the Z-direction. The first channel CH1 and the second channel CH2 are separated from each other.

A longitudinal direction of each of the first channel CH1 and the second channel CH2 may be arranged in a direction (Z-direction) perpendicular to a substrate (not shown). The aluminum oxide layer 231 of the first channel CH1 and the aluminum oxide layer 231 of the second channel CH2 may be arranged at positions that satisfy Equation 1.

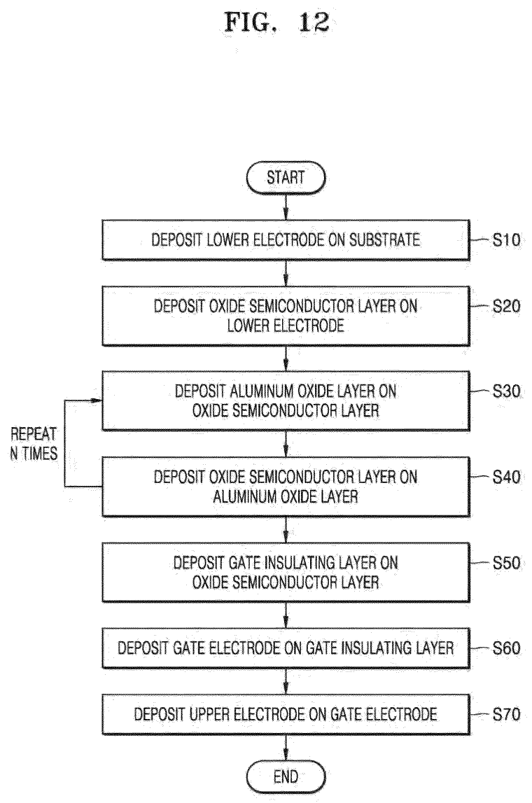

FIG. 12 is a flowchart illustrating a method of manufacturing a semiconductor device, according to at least one embodiment.

A lower electrode is deposited on a substrate (S10), and an oxide semiconductor layer is deposited on the lower electrode (S20). The oxide semiconductor layer may be deposited by using, for example, an atomic layer deposition (ALD) process, plasma-enhanced ALD (PE-ALD) process, and/or the like. An aluminum oxide layer may be deposited on the oxide semiconductor layer (S30). The aluminum oxide layer may be deposited by using an ALD process. The oxide semiconductor layer may be deposited again on the aluminum oxide layer by using an ALD process. Operation S30 and operation S40 may be repeated n times. In this case, n may be 10 or less. Alternatively, n may be 5 or less. Alternatively, n may be 3 or less. A channel may be formed in operations S20, S30, and S40. The oxide semiconductor layer, the aluminum oxide layer, and an oxide semiconductor layer may form a minimum channel, and the number of oxide semiconductor layers and the number of aluminum oxide layers may be adjusted within a ratio of at least about 1% but no more than about 30% of a sum of thicknesses of the aluminum oxide layers to a total thickness of the channel.

A gate insulating layer is deposited on a final oxide semiconductor layer (S50). Then, a gate electrode is deposited on the gate insulating layer (S60). An upper electrode is deposited on the gate electrode (S70).

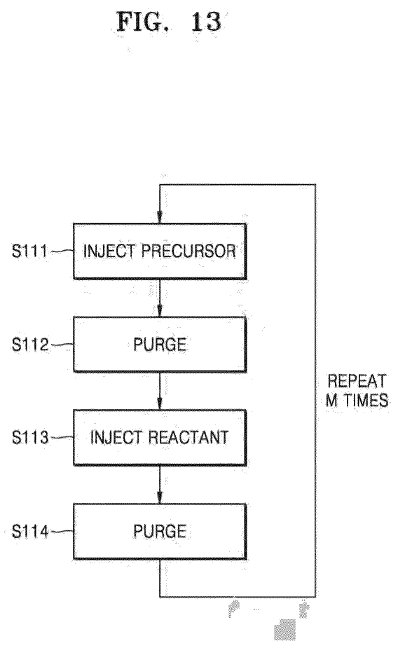

FIG. 13 is a flowchart illustrating a process of depositing an oxide semiconductor layer and an aluminum oxide layer. Referring to FIG. 13, depositing the oxide semiconductor layers (S20, S40) and depositing the aluminum oxide layer (S30) may include an ALD process. The ALD process may include injecting a precursor into a chamber (S111), purging (S112), injecting a reactant into the chamber and causing the reactant to react with the precursor (S113), and purging (S114). Operations S111, S112, S113, and S114 may be repeated m times (m is a natural number), for example, about 1 to about 100 times. Alternatively, m may be in a range of about 1 to about 70.

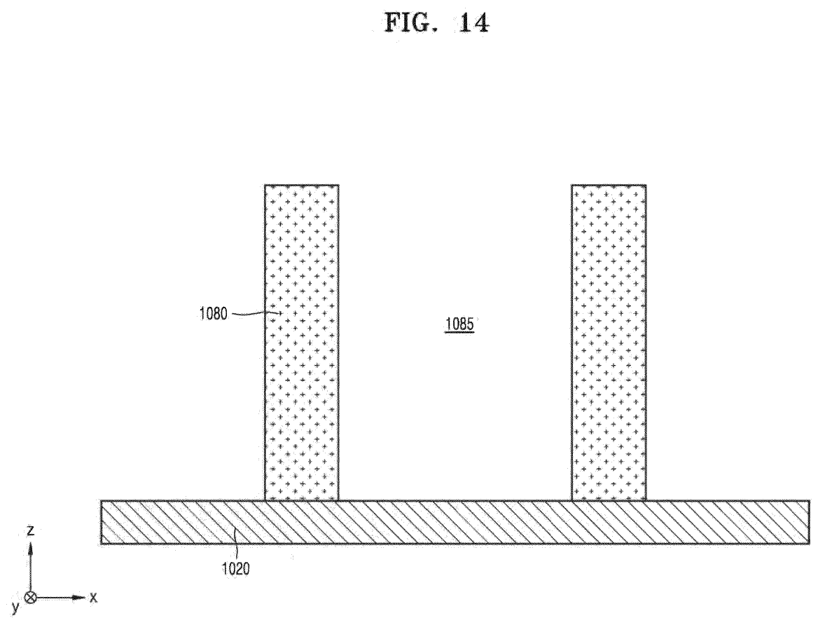

Next, the method of manufacturing a semiconductor device according to at least one embodiment is described with reference to FIGS. 14 to 27.

Referring to FIG. 14, a plurality of mold insulating layers 1080 extending in a second horizontal direction (y) may be deposited on a lower electrode 1020 extending in the first horizontal direction (x). The mold insulating layers 1080 may be stacked until the mold insulating layers 1080 have a certain height in a vertical direction (z). The plurality of mold insulating layers 1080 and the lower electrode 1020 may form an opening 1085.

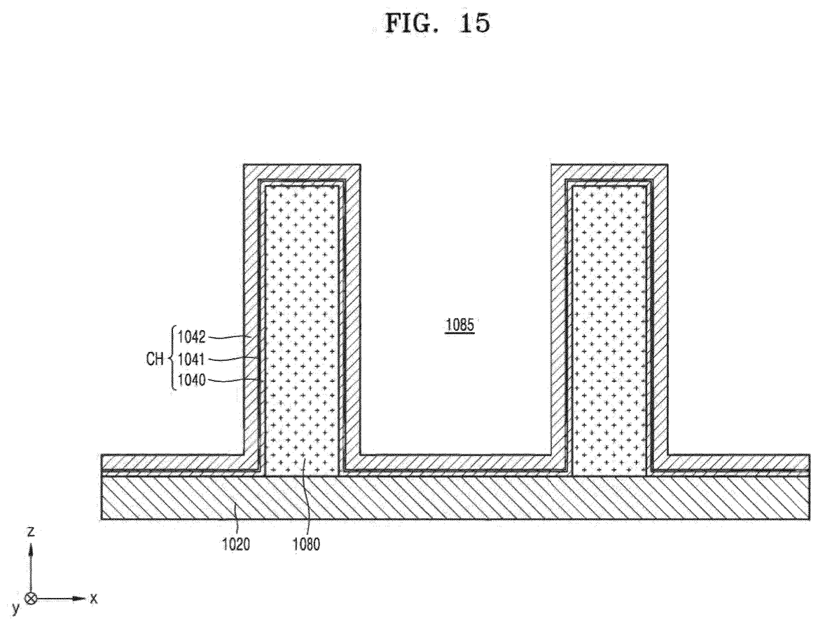

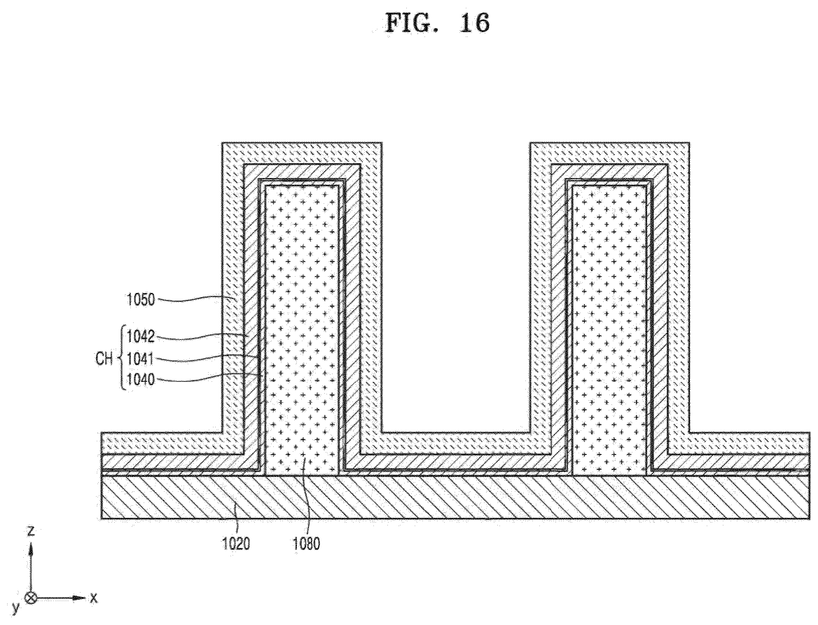

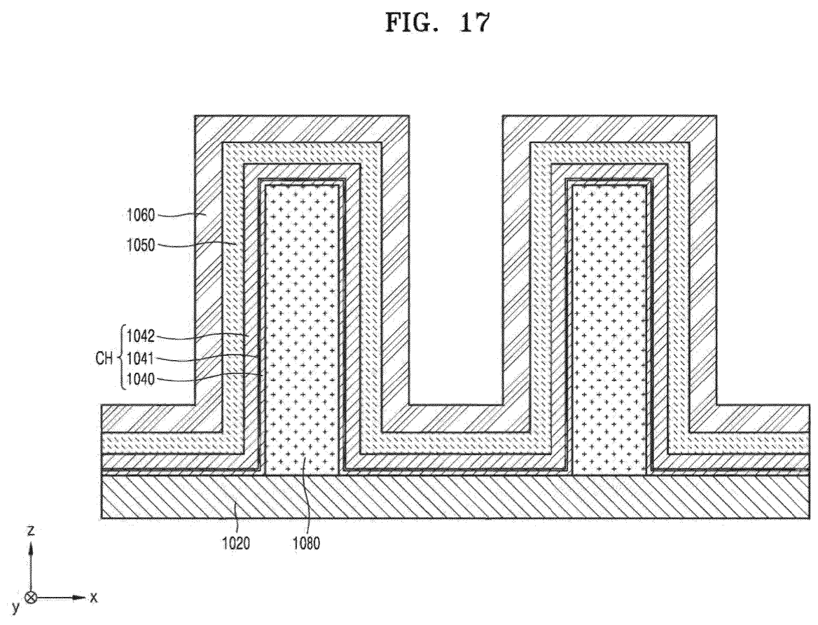

Referring to FIG. 15, a first oxide semiconductor layer 1040, an aluminum oxide layer 1041, and a second oxide semiconductor layer 1042 may be deposited on the lower electrode 1020 and the mold insulating layers 1080. The first oxide semiconductor layer 1040, the aluminum oxide layer 1041, and the second oxide semiconductor layer 1042 may configure a channel CH. The first oxide semiconductor layer 1040, the aluminum oxide layer 1041, and the second oxide semiconductor layer 1042 may be deposited by using an ALD method. The channel CH may have a U-shaped cross-sectional shape. Referring to FIG. 16, a gate insulating layer 1050 may be deposited on the second oxide semiconductor layer 1042. Referring to FIG. 17, a gate electrode 1060 may be deposited on the gate insulating layer 1050.

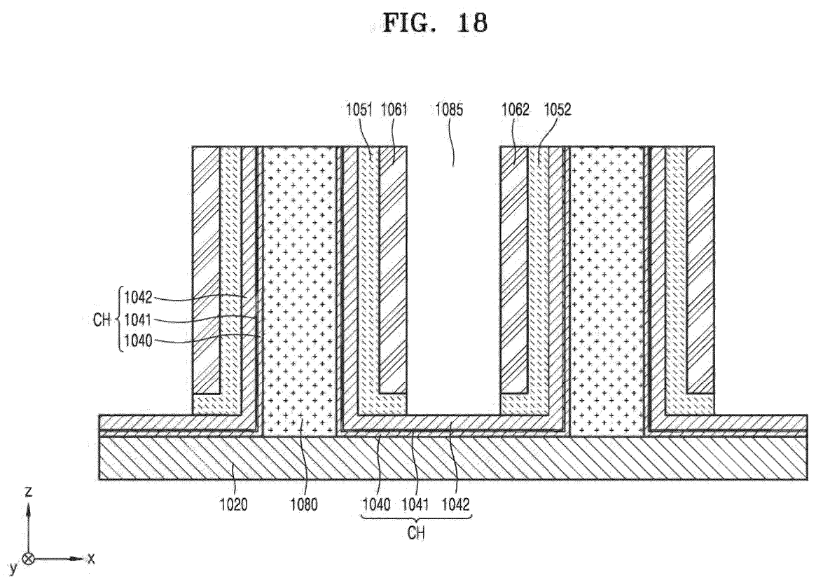

Referring to FIG. 18, anisotropic etching is performed on the gate electrode 1060 in a structure shown in FIG. 17 such that the second oxide semiconductor layer 1042 may be exposed. As a result, the gate electrode 1060 may be separated into a first gate electrode 1061 and a second gate electrode 1062, and the gate insulating layer 1050 may be separated into a first gate insulating layer 1051 and a second gate insulating layer 1052. Also, the gate electrode 1060, the gate insulating layer 1050, and the channel CH are etched toward the upper surfaces of the mold insulating layers 1080 such that the upper surface of the mold insulating layers 1080 may be exposed. Levels of the upper surfaces of the mold insulating layers 1080, the upper surface of the channel CH, the upper surfaces of the first gate electrode 1061 and the second gate electrode 1062, and the upper surfaces of the first gate insulating layer 1051 and the second gate insulating layer 1052 may match each other.

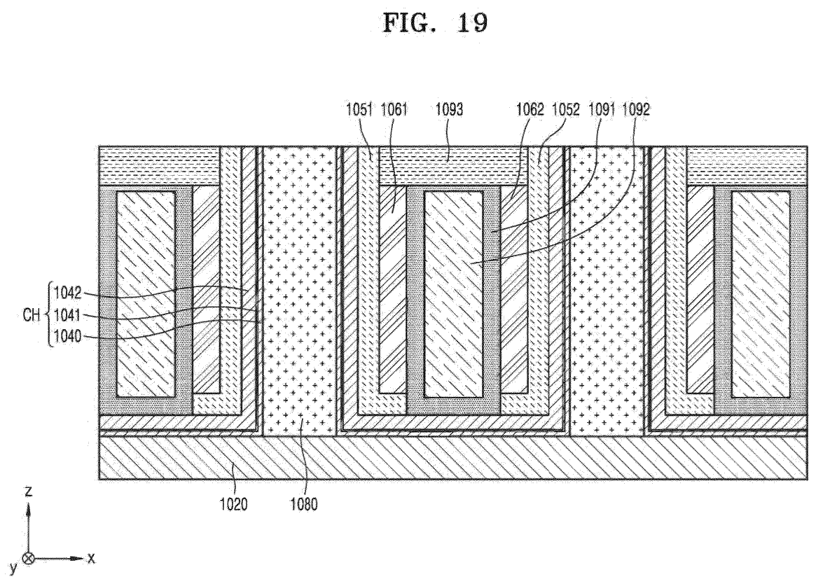

Referring to FIG. 19, when the gate electrode 1060 is etched once more, the levels of the upper surfaces of the first gate electrode 1061 and the second gate electrode 1062 may be lower than the levels of the upper surfaces of the mold insulating layers 1080.

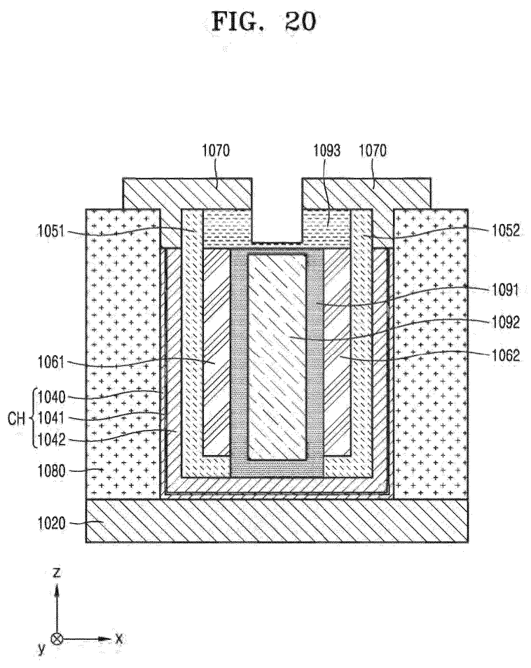

Referring to FIG. 20, an insulating liner 1091 may be deposited from the bottom surface of the second oxide semiconductor layer 1042 to the levels of the upper surfaces of the first gate electrode 1061 and/or the second gate electrode 1062. The inside of the insulating liner 1091 may be filled with a buried insulating layer 1092. The insulating liner 1091 and the buried insulating layer 1092 may include the same material. An upper insulating layer 1093 may be deposited on the upper surfaces of the first gate electrode 1061 and/or the second gate electrode 1062 and the upper surface of the insulating liner 1091. A surface level of the upper insulating layer 1093 may match the levels of the upper surfaces of the mold insulating layers 1080, the upper surface of the channel CH, the upper surfaces of the first gate electrode 1061 and the second gate electrode 1062, and the upper surfaces of the first gate insulating layer 1051 and the second gate insulating layer 1052.

For convenience of illustration, FIG. 20 shows only a portion corresponding to one of the two pixels in FIG. 19. Referring to FIG. 20, a portion of the upper surface of the channel CH may be etched, and an upper portion 1070 may be deposited on the upper surface of the channel CH. After the upper portion 1070 is deposited, a central portion of the upper portion 1070 and an upper portion of the upper insulating layer 1093 may be partially etched.

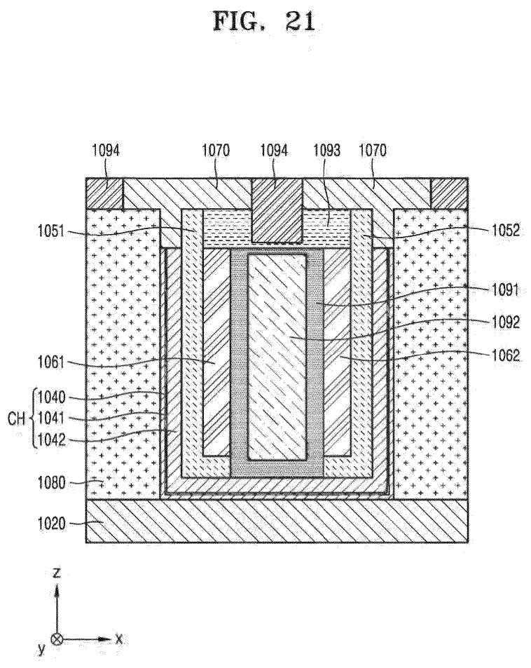

Referring to FIG. 21, an insulating layer 1094 may be deposited between the upper portion 1070 and the upper portion 1070 and on a portion of the upper portion of the upper insulating layer 1093. A level of the upper surface of the insulating layer 1094 and a surface level of the upper portion 1070 may be the same.

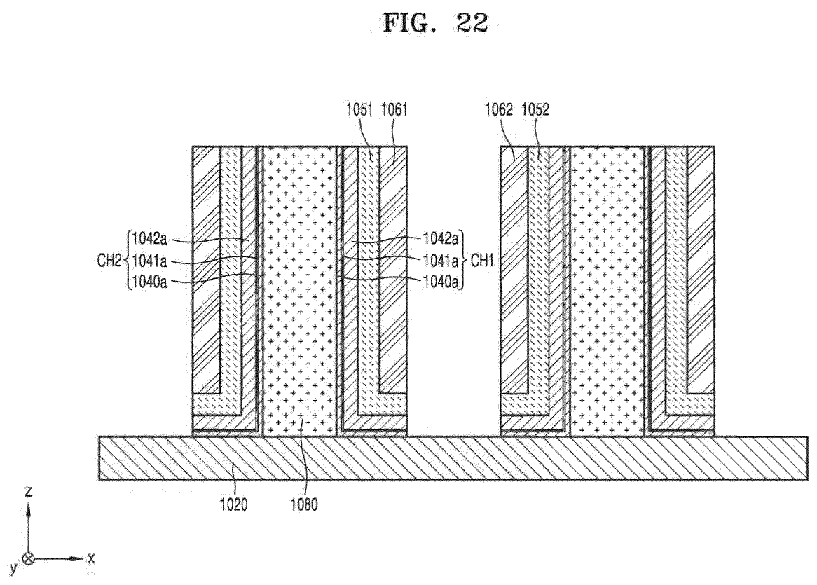

FIG. 22 is a diagram to describe a method of manufacturing the semiconductor device shown in FIG. 11. Hereinafter, descriptions that are substantially the same as those of FIG. 18 are omitted, and the differences are mainly described.

Referring to FIG. 22, the gate electrode 1060, the gate insulating layer 1050, and the channel CH are etched toward the bottom of the opening 1085 such that a portion of the surface of the lower electrode 1020 may be exposed. Accordingly, the channel CH may be separated into the first channel CH1 and the second channel CH2. The first channel CH1 and the second channel CH2 may each include a first oxide semiconductor layer 1040a, an aluminum oxide layer 1041a, and a second oxide semiconductor layer 1042a.

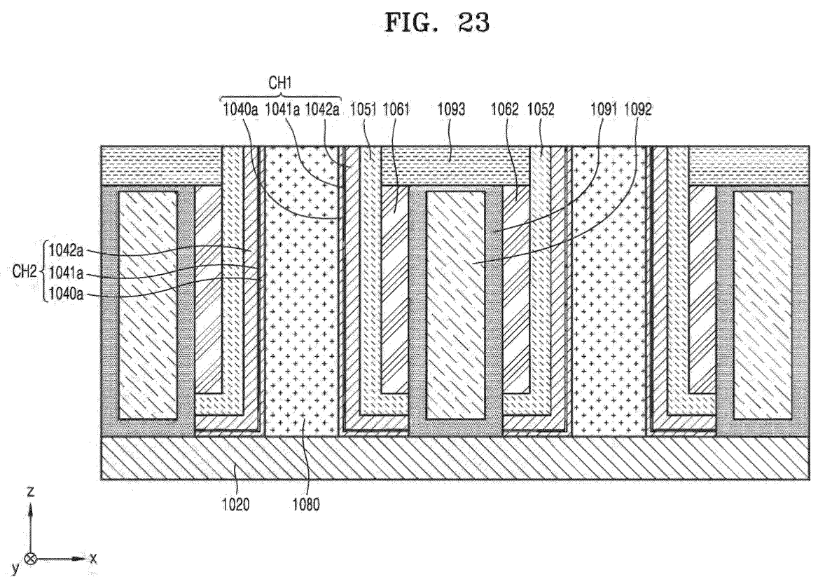

Referring to FIG. 23, the insulating liner 1091 may be deposited from the upper surface of the lower electrode 1020 to the levels of the upper surfaces of the first gate electrode 1061 and/or the second gate electrode 1062.

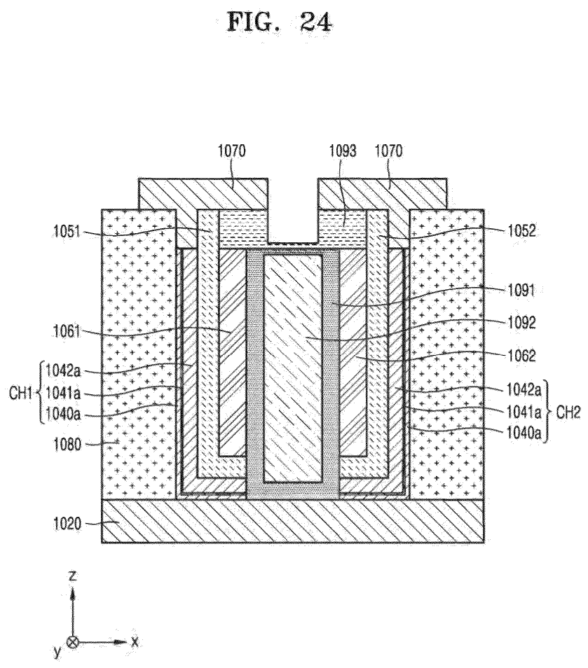

Referring to FIG. 24, similar to FIG. 20, portions of the upper surfaces of the first channel CH1 and the second channel CH2 may be etched, and the upper portion 1070 may be deposited on the upper surfaces of the first channel CH1 and the second channel CH2. After the upper portion 1070 is deposited, the central portion of the upper portion 1070 and the upper portion of the upper insulating layer 1093 may be partially etched.

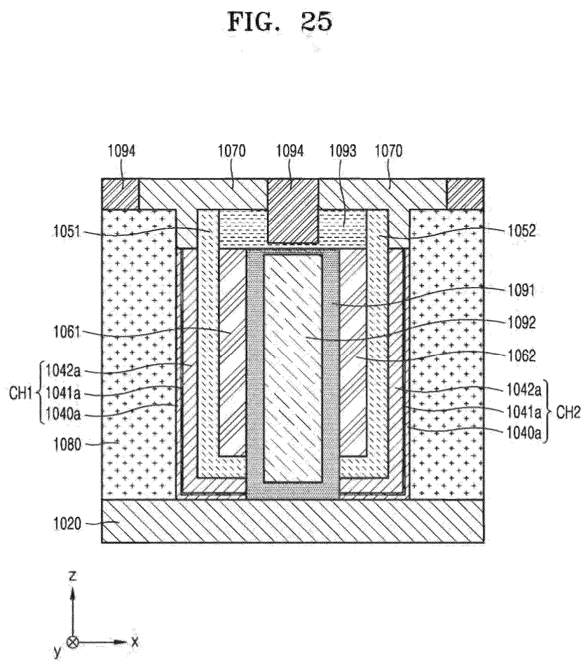

Referring to FIG. 25, similar to FIG. 21, the insulating layer 1094 may be deposited between the upper portion 1070 and the upper portion 1070 and on a portion of the upper portion of the upper insulating layer 1093. The level of the upper surface of the insulating layer 1094 may match the surface level of the upper portion 1070.

As described above, the semiconductor device according to at least one embodiment may form a channel including an oxide semiconductor layer and an aluminum oxide layer by using an ALD process.

The semiconductor device according to at least one embodiment may be applied to, for example, a transistor, a field-effect transistor (FET), a semiconductor memory device, a logic device, an image sensor, etc. The logic device is responsible for calculation and control, and the memory device is responsible for information storage. The logic device may be applied to a micro component, an analog IC, a logic IC, etc. The analog IC may include a power semiconductor, an image sensor, a touch sensor, etc. The logic IC may include a display driver IC (DDI), a timing controller (T-CON), a media IC, an application processor (AP), an automotive semiconductor, etc. The memory device may include DRAM, static RAM (SRAM), NOT-AND (NAND) memory, etc.

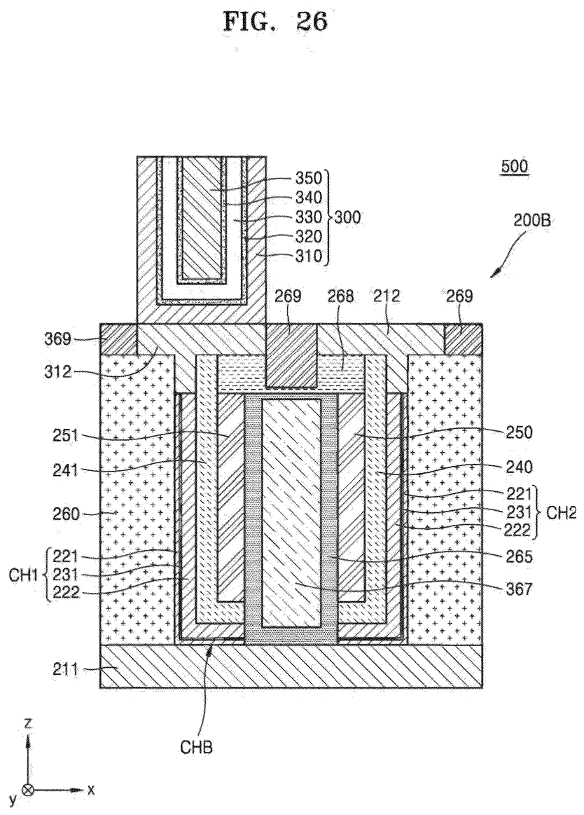

FIG. 26 shows an example in which the semiconductor device 200B is applied to DRAM, according to at least one embodiment. Because the semiconductor device 200B is the same as (and/or substantially similar to) that described with reference to FIG. 11, a detailed description thereof is omitted for brevity.

Referring to FIG. 26, a memory device 500 may include the semiconductor device 200B and a capacitor 300 connected to the upper electrode 212 of the semiconductor device 200B.

The capacitor 300 may include a first electrode 310, a dielectric film 330, and a second electrode 350. For example, the dielectric film 330 may include at least one of HfO₂, ZrO₂, CeO₂, La₂O₃, Ta₂O₃, and TiO₂. A lower interface film 320 may be further provided between the first electrode 310 and the dielectric film 330. The lower interface film 320 may include a material expressed as MM′ON, M′O, or M′ON. The M may include any one of Be, B, Na, Mg, Al, Si, K, Ca, Sc, Ti, V, Cr, Mn, Fe, Co, Ni, Cu, Zn, Ga, Ge, Rb, Sr, Y, Zr, Nb, Mo, Tc, Ru, Rh, Pd, Ag, Cd, In, Sn, Sb, Te, Cs, Ba, La, Ce, Pr, Nd, Pm, Sm, Eu, Gd, Tb, Dy, Ho, Er, Tm, Yb, Lu, Hf, Ta, W, Re, Os, Ir, Pt, Au, Hg, Tl, Pb, Bi, Po, Fr, Ra, Ac, Th, Pa, and U, and the M′ may include any one of H, Li, Be, B, N, O, Na, Mg, Al, Si, P, S, K, Ca, Sc, Ti, V, Cr, Mn, Fe, Co, Ni, Cu, Zn, Ga, Ge, As, Se, Rb, Sr, Y, Zr, Nb, Mo, Tc, Ru, Rh, Pd, Ag, Cd, In, Sn, Sb, Te, Cs, Ba, La, Ce, Pr, Nd, Pm, Sm, Eu, Gd, Tb, Dy, Ho, Er, Tm, Yb, Lu, Hf, Ta, W, Re, Os, Ir, Pt, Au, Hg, TI, Pb, Bi, Po, Fr, Ra, Ac, Th, Pa, and U. A leakage current reduction film 340 may be further provided between the dielectric film 330 and the second electrode 350. The leakage current reduction film 340 may include, for example, an AlZrO film. However, the leakage current reduction film 340 is not limited thereto.

As described above, when the semiconductor device 200B according to at least one embodiment is applied to the memory device 400, even when the memory device 400 is miniaturized, the semiconductor device 200B includes at least one aluminum oxide layer 231 in the channel CH, and may thus reduce leakage current and improve thermal stability.

In FIG. 26, the semiconductor devices 100, 100A, 200, and 200A according to other embodiments, which have been described with reference to FIGS. 1, 8, 9, and 10, may also be applied instead of the semiconductor device 200B.

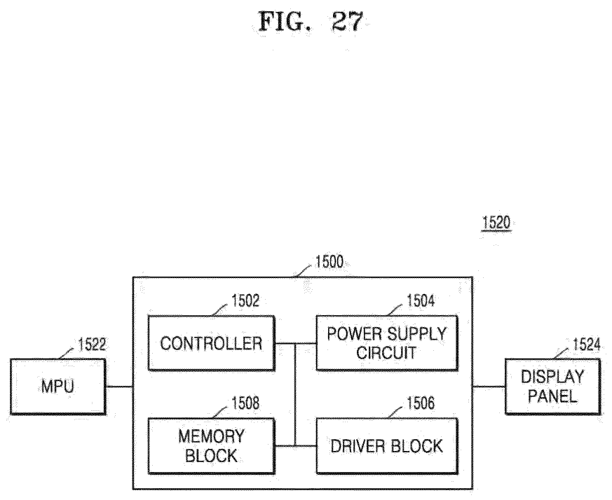

FIG. 27 is a schematic block diagram of a DDI 1500 and a display apparatus 1520 including the DDI 1500, according to at least one embodiment.

Referring to FIG. 27, the DDI 1500 may include a controller 1502, a power supply circuit 1504, a driver block 1506, and a memory block 1508. The controller 1502 receives and decodes commands issued from a main processing unit (MPU) 1522 and controls respective blocks of the DDI 1500 to implement operations according to the commands. The power supply circuit 1504 generates a driving voltage in response to the control by the controller 1502. The driver block 1506 drives a display panel 1524 by using the driving voltage generated by the power supply circuit 1504 in response to the control by the controller 1502. The display panel 1524 may be a liquid crystal display panel or a micro light-emitting diode (LED) apparatus. The memory block 1508 is a block that temporarily stores commands input to the controller 1502 or control signals output from the controller 1502 or stores necessary data, and may include a memory such as RAM or read-only memory (ROM). The power supply circuit 1504 and the driver block 1506 may include the semiconductor device according to the aforementioned embodiment.

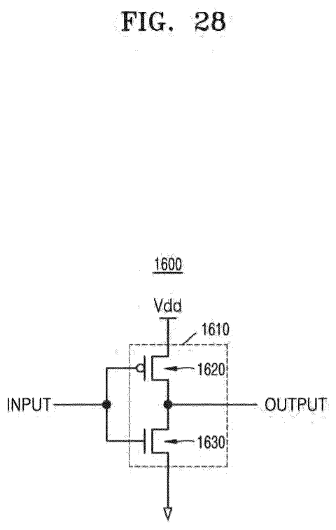

FIG. 28 is a circuit diagram of a complementary metal-oxide-semiconductor (CMOS) inverter 1600 according to at least one embodiment.

The CMOS inverter 1600 includes a CMOS transistor 1610. The CMOS transistor 1610 includes a p-channel MOS (PMOS) transistor 1620 and an n-channel MOS (NMOS) transistor 1630, which are connected between a power terminal Vdd and a ground terminal. The CMOS transistor 1610 may include the semiconductor device according to the aforementioned embodiment.

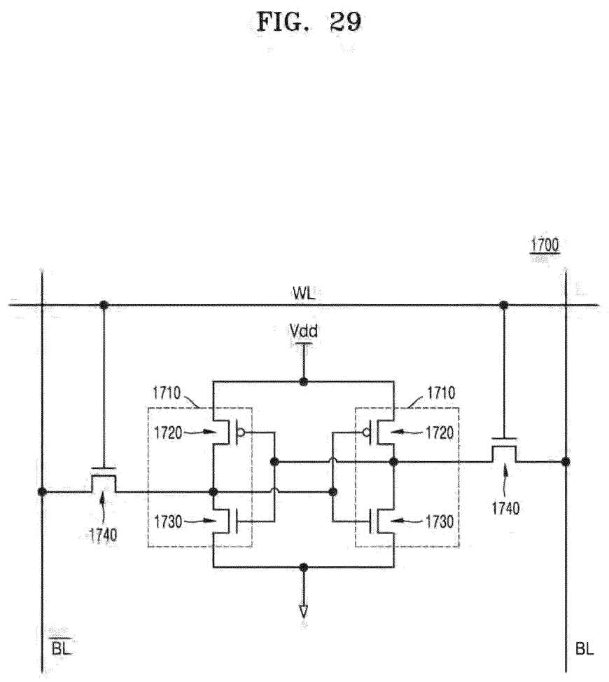

FIG. 29 is a circuit diagram of a CMOS SRAM device 1700 according to at least one embodiment.

The CMOS SRAM device 1700 includes a pair of driving transistors 1710. Each of the pair of driving transistors 1710 includes a p-type MOS (PMOS) transistor 1720 and an n-type MOS (NMOS) transistor 1730, which are connected between the power terminal Vdd and a ground terminal. The CMOS SRAM device 1700 may further include a pair of transmission transistors 1740. A source of each of the transmission transistors 1740 is cross-connected to a common node of the PMOS transistor 1720 and the NMOS transistor 1730, which constitute each of the driving transistors 1710. The power terminal Vdd is connected to a source of the PMOS transistor 1720, and the ground terminal is connected to a source of the NMOS transistor 1730. A word line WL may be connected to a gate of each of the pair of transmission transistors 1740, and a bit line BL and an inverted bit line may be respectively connected to drains of the pair of transmission transistors 1740.

At least one of the driving transistors 1710 and the transmission transistors 1740 of the CMOS SRAM device 1700 may include the semiconductor device according to the aforementioned embodiment.

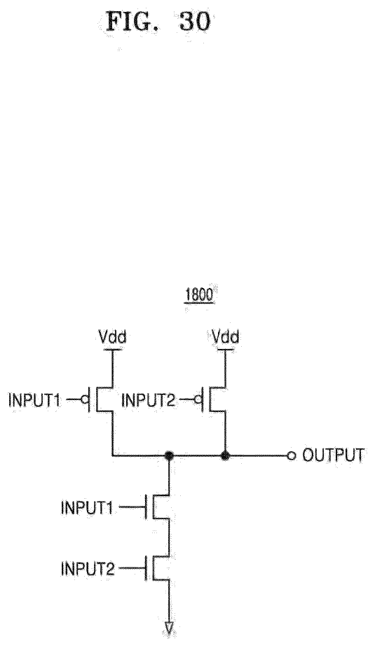

FIG. 30 is a circuit diagram of a CMOS NAND circuit 1800 according to at least one embodiment.

The CMOS NAND circuit 1800 includes a pair of CMOS transistors to which different input signals are transmitted. The CMOS NAND circuit 1800 may include the semiconductor device according to the aforementioned embodiment.

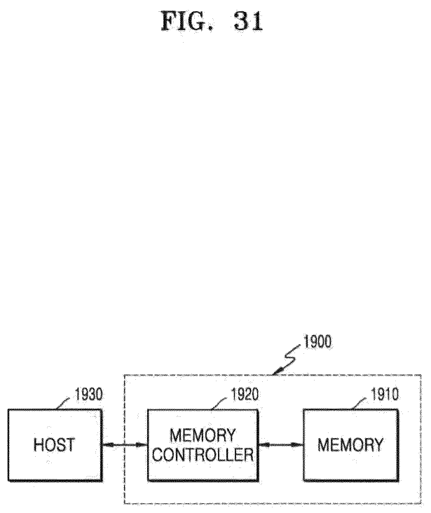

FIG. 31 is a block diagram of an electronic system 1900 according to at least one embodiment.

The electronic system 1900 includes a memory 1910 and a memory controller 1920. The memory controller 1920 may control the memory 1910 to read data from the memory 1910 and/or to write data into the memory 1910 in response to a request from a host 1930. At least one of the memory 1910 and the memory controller 1920 may include the semiconductor device according to the aforementioned embodiment.

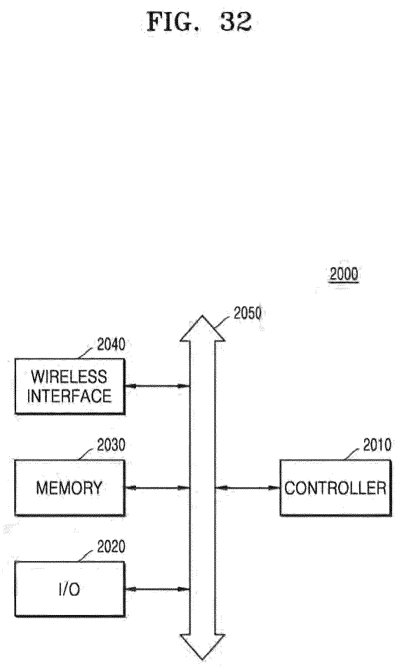

FIG. 32 is a block diagram of an electronic system 2000 according to at least one embodiment.

The electronic system 2000 may configure a wireless communication apparatus or an apparatus capable of transmitting and/or receiving information in a wireless environment. The electronic system 2000 includes a controller 2010, an input/output (I/O) 2020, a memory 2030, and a wireless interface 2040, and these elements are interconnected through a bus (2050).

The controller 2010 may include at least one of a microprocessor, a digital signal processor, or a similar processing apparatus. The I/O 2020 may include at least one of a keypad, a keyboard, or a display. The memory 2030 may be used to store commands executed by the controller 2010. For example, the memory 2030 may be used to store user data. The electronic system 2000 may use the wireless interface 2040 to transmit/receive data through a wireless communication network. The wireless interface 2040 may include an antenna and/or a wireless transceiver. The electronic system 2000 may include the semiconductor device according to the aforementioned embodiment.

The semiconductor device according to the embodiment has an ultra-small structure and may exhibit good electrical performance, and thus may be applied to an integrated circuit device and may achieve miniaturization, low power, and high performance.

The aforementioned semiconductor device and the method of manufacturing the same have been described with reference to the embodiments shown in the drawings, but these are merely examples, and it should be understood that various modifications and other equivalent embodiments may be made by those of ordinary skill in the art. Although many details are described in the above description, they should be construed as examples of specific embodiments rather than limiting the scope of the disclosure. Therefore, the scope of the disclosure should not be determined by the described embodiments, but rather by the technical idea stated in the claims.

The semiconductor device according to the embodiment includes an oxide semiconductor layer and an aluminum oxide layer and may thus improve thermal stability. The aluminum oxide layer may control the distribution of oxygen and hydrogen inside a channel and at an interface with a gate insulating layer, thereby improving electrical and thermal reliability of the semiconductor device.

It should be understood that the embodiments described herein should be considered in a descriptive sense only and not for purposes of limitation. Descriptions of features or aspects within each of the embodiments should typically be considered as available for other similar features or aspects in other embodiments. While one or more embodiments have been described with reference to the figures, it will be understood by one of ordinary skill in the art that various changes in form and details may be made therein without departing from the spirit and scope as defined by the following claims.

What is claimed is:

1. A semiconductor device comprising:
a lower electrode;
an upper electrode spaced apart from the lower electrode;
a channel between the lower electrode and the upper electrode, the channel including at least one aluminum oxide layer and a plurality of oxide semiconductor layers, each of the at least one aluminum oxide layer between two of the plurality of oxide semiconductor layers;
a gate electrode on the channel; and
a gate insulating layer between the gate electrode and the channel,
wherein the channel is configured such that each of the plurality of oxide semiconductor layers and the at least one aluminum oxide layer extends in a first direction from the lower electrode to the upper electrode,
wherein each of the plurality of oxide semiconductor layers includes indium (In), zinc (Zn), and oxygen (O) or includes In, aluminum (Al), Zn, and O,
wherein the channel is in an amorphous state, and
wherein the at least one aluminum oxide layer is located in an area that satisfies a following equation
0.05D≤L≤0.35D <Equation>
wherein L refers to a distance from a center line in a thickness direction of the channel to the at least one aluminum oxide layer, and D refers to a total thickness of the channel in the thickness direction.

2. The semiconductor device of claim 1, wherein the total thickness of the channel is in a range of 1 nanometer (nm) to 10 nm.

3. The semiconductor device of claim 1, wherein a thickness of the at least one aluminum oxide layer, in the thickness direction, is in a range of 0.1 nanometer (nm) to 3 nm.

4. The semiconductor device of claim 1, wherein a ratio of a thickness of the at least one aluminum oxide layer to the total thickness of the channel is in a range of 1% to 30%.

5. The semiconductor device of claim 1, wherein a number of the at least one aluminum oxide layer is in a range of 1 to 6.

6. The semiconductor device of claim 1, wherein the channel has an Al ratio to other metal elements, excluding O, in a range of 0.1 at % to 33 at %.

7. The semiconductor device of claim 1, wherein a content ratio (Al/In) of Al to In in the channel is in a range of 0.01 to 1.

8. The semiconductor device of claim 1, wherein an interface of the at least one aluminum oxide layer is in direct contact with the two of the plurality of oxide semiconductor layers.

9. The semiconductor device of claim 1, wherein the semiconductor device has a gate all around structure.

10. The semiconductor device of claim 1, wherein the channel, the gate insulating layer, and the gate electrode are arranged such that a longitudinal direction of each of the channel, the gate insulating layer, and the gate electrode is perpendicular to the semiconductor device, and the channel, the gate insulating layer, and the gate electrode are arranged in a direction horizontal to the semiconductor device.

11. The semiconductor device of claim 1, wherein the channel has a U-shaped cross-section.

12. The semiconductor device of claim 1, wherein the channel includes a first channel and a second channel, the first channel having an L-shaped cross-sectional shape, and the second channel being symmetrically arranged with the first channel with respect to a direction perpendicular to the semiconductor device.

13. A method of manufacturing a semiconductor device, the method comprising:
depositing a lower electrode on a substrate;
forming a channel by depositing a first oxide semiconductor layer on the lower electrode, depositing an aluminum oxide layer on the first oxide semiconductor layer, and depositing a second oxide semiconductor layer on the aluminum oxide layer;
depositing a gate insulating layer on the second oxide semiconductor layer;
depositing a gate electrode on the gate insulating layer; and
depositing an upper electrode on the gate electrode,
wherein each of the first oxide semiconductor layer and the second oxide semiconductor layer includes indium (In), zinc (Zn), and oxygen (O) or includes In, aluminum (Al), Zn, and O,
wherein the forming the channel includes forming the channel such that channel is in an amorphous state, and
wherein the forming channel include forming the first and second oxide semiconductor layers such that the aluminum oxide layer is located in an area that satisfies a following equation
0.05D≤L≤0.35D <Equation>
where L refers to a distance from a center line in a thickness direction of the channel to the aluminum oxide layer, and D refers to a total thickness of the channel.

14. The method of claim 13, wherein the forming the channel include an atomic layer deposition.

15. The method of claim 13, wherein the forming of the channel includes forming the channel such that the total thickness of the channel is in a range of 1 nanometers (nm) to 10 nm.

16. The method of claim 13, wherein the depositing the aluminum oxide layer includes forming the aluminum oxide layer such that the aluminum oxide layer has a thickness in a range of 0.1 nanometers (nm) to 3 nm.

17. The method of claim 13, wherein the forming of the channel includes forming the channel such that a ratio of a thickness of the aluminum oxide layer to the total thickness of the channel is in a range of 1% to 30%.

18. The method of claim 13, wherein the forming of the channel includes performing the depositing the aluminum oxide layer and the depositing the second semiconductor oxide layer one or more times, such that the channel includes 1 to 6 of the aluminum oxide layer.

19. The method of claim 13, wherein the forming of the channel includes forming the channel such that the channel has an Al ratio to other metal elements, excluding O, in a range of 0.1 at % to 33 at %.

20. The method of claim 13, wherein the forming of the channel includes forming the channel such that a content ratio (Al/In) of Al to In in the channel is in a range of 0.01 to 1.
